(19) United States
(12) Patent Application Publication
(10) Pub. No.: US 2010/0224874 A1
(43) Pub. Date: Sep. 9, 2010

(54) TCP-type semiconductor device

(75) Inventor: Suguru Sasaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/659,272

(22) Filed: Mar. 2, 2010

(30) Foreign Application Priority Data
Mar. 4, 2009 (JP) 2009-051307

(51) Int. Cl. H01L 23/544

(52) U.S. Cl. 257/48; 257/E23.179

(57) ABSTRACT

A TCP-type semiconductor device has: a base film; a semiconductor chip mounted on the base film; and a plurality of leads formed on the base film and electrically connected to the semiconductor chip. Each of the plurality of leads has a test pad section at a position other than both ends of the each lead.

### INCORPORATION BY REFERENCE

This application is based upon and claims the benefit of priority from Japanese patent application No. 2009-051307 filed on Mar. 4, 2009, the disclosure of which is incorporated herein in its entirety by reference.

### BACKGROUND OF THE INVENTION

1. Field of the Invention

The present invention relates to a semiconductor device and a method of testing thereof. In particular, the present invention relates to a TCP (Tape Carrier Package) type semiconductor device and a method of testing thereof.

2. Description of Related Art

A probe card used for testing a semiconductor device is publicly known. The probe card has a large number of probes that come in contact with test terminals of a test target. The test is performed by bringing respective ends of the probes into the corresponding test terminals, supplying a test signal from a tester to the test target through the probe card and retrieving an output signal from the test target. At this time, it is required to correctly bring each probe into one-on-one contact with the corresponding test terminal so as not to cause a short failure and the like.

On the other hand, a pitch between adjacent test terminals is getting narrower due to recent miniaturization and increase in the number of terminals of the semiconductor device. Therefore, the probe card also needs to follow the narrowing of the test terminal pitch. For example, it may be considered to narrow a pitch between ends of adjacent probes of the probe card following the narrowing of the test terminal pitch. However, there is a limit to the narrowing of the pitch between the probe ends because electrical isolation must be ensured between the adjacent probes. Consequently, it is proposed to distribute positions of the probe ends over a plurality of rows. Due to this configuration, it is possible to narrow a substantive pitch between the probe ends while ensuring the electrical isolation between the probes, which enables following the narrowing of the test terminal pitch. Probe cards having such the probe pattern are disclosed, for example, in Japanese Patent Publication JP-H08-94668A, Japanese Patent Publication JP-H08-222299A and Japanese Utility Model Publication JP-H04-5643A.

Moreover, a TCP (Tape Carrier Package) type semiconductor device is publicly known. In the case of the TCP, a semiconductor chip is mounted on a base film such as a TAB (Tape Automated Bonding) tape. The TCP-type semiconductor device also includes the so-called COF (Chip On Film).

FIG. 1 is a plan view schematically showing the TCP-type semiconductor device disclosed in Japanese Patent Publication JP-2004-356339. In FIG. 1, a semiconductor chip 120 is mounted on a base film (carrier tape) 110. Moreover, a plurality of leads 130 and a plurality of contact pads 140 are formed on the base film 110. The plurality of leads 130 electrically connect between the semiconductor chip 120 and the plurality of contact pads 140, respectively.

More specifically, as shown in FIG. 1, solder resist SR is so formed as to partially cover each lead 130. The solder resist SR is resin applied on the lead 130 and plays roles of not only electrically isolating the leads 130 but also relaxing chemical stress such as corrosion and physical stress on the leads 130 due to external force. The lead 130 in a region where the solder resist SR is not formed serves as a terminal that is electrically connectable to the outside, and the region is a terminal region. The semiconductor chip 120 is mounted on a central terminal region in which the solder resist SR is not formed, and then it is resin-sealed. On the other hand, an outside terminal region in which the solder resist SR is not formed is an external terminal region and is electrically connected to the contact pads 140.

The contact pads 140 are test terminals used at the time of testing the semiconductor chip 120 and are placed within a predetermined region (pad placement region RP) on the base film 110. That is, at the time of testing the semiconductor chip 120, the probes of the probe card come in contact with the contact pads 140 within the pad placement region RP. Then, a test signal is supplied to the semiconductor chip 120 and an output signal is retrieved from the semiconductor chip 120 through the contact pads 140 and the leads 130. It should be noted that the probe card used here also has the probe pattern where positions of the probe ends are distributed over a plurality of rows. Corresponding to the probe pattern, the contact pads 140 also are distributed over a plurality of rows as shown in FIG. 1.

In FIG. 1, a width direction and an extending direction of the base film 110 are x-direction and y-direction, respectively. The structure shown in FIG. 1 is formed repeatedly along the y-direction. On separating the semiconductor chip 120 one by one after the test, the base film 110 and the plurality of leads 130 are cut along a cut line CL indicated by a dashed line in FIG. 1. At this time, the contact pads 140 in the pad placement region RP remain on the base film 110.

The inventor of the present application has recognized the following point. In recent years, the number of terminals of the semiconductor chip is increasing, and thus the numbers of test signals supplied to the semiconductor chip and output signals retrieved from the semiconductor chip at the time of the test also are increasing. This means increase in the number of contact pads 140 of the TCP-type semiconductor device shown in FIG. 1. The increase in the number of contact pads 140 leads to enlargement of the pad placement region RP and thus to increase in the width and length of the base film 110. As a result, costs of manufacturing the TCP-type semiconductor device are increased. Therefore, a technique that can reduce the costs of manufacturing the TCP-type semiconductor device is desired.

### SUMMARY

In one embodiment of the present invention, a TCP-type semiconductor device is provided. The TCP-type semiconductor device has: a base film; a semiconductor chip mounted on the base film; and a plurality of leads formed on the base film and electrically connected to the semiconductor chip. Each of the plurality of leads has a test pad section at a position other than both ends of the each lead.

In another embodiment of the present invention, a TCP-type semiconductor device is provided. The TCP-type semiconductor device has a base film and a plurality of semiconductor devices. The base film has a plurality of device regions each of which is surrounded by a cut line. The base film is cut along the cut line. The plurality of semiconductor devices are placed within the plurality of device regions, respectively. Each of the plurality of semiconductor devices has: a semiconductor chip mounted on the base film; and a plurality of leads formed on the base film and electrically connected to the semiconductor chip. Each of the plurality of leads has a test pad section at a position other than both ends of the each lead.

According to the present invention, the costs of manufacturing the TCP-type semiconductor device can be reduced.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view schematically showing a typical TCP type semiconductor device;

FIG. 2 is a plan view schematically showing a TCP type semiconductor device according to an embodiment of the present invention;

FIG. 3 is a plan view showing the TCP type semiconductor device as one unit according to the present embodiment;

FIG. 4 is a plan view showing a test pad section of a lead according to the present embodiment;

FIG. 5 is a plan view showing one example of arrangement of respective test pad sections of a plurality of leads according to the present embodiment;

FIG. 6 is a plan view showing another example of arrangement of respective test pad sections of the plurality of leads according to the present embodiment;

FIG. 7 is a plan view showing a modification example of the test pad section according to the present embodiment;

FIG. 8 is a plan view showing another modification example of the test pad section according to the present embodiment; and

FIG. 9 is a plan view showing still another modification example of the test pad section according to the present embodiment.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

A semiconductor device and a method of testing thereof according to an embodiment of the present invention will be described below with reference to the attached drawings.

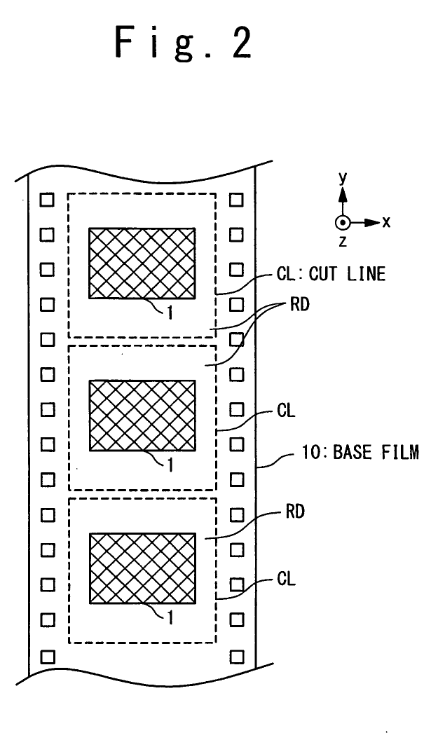

FIG. 2 schematically shows a configuration of a TCP type semiconductor device according to the present embodiment. In the TCP type semiconductor device, a base film (carrier tape) 10 such as a TAB tape is used. As shown in FIG. 2, a width direction and an extending direction of the base film 10 are an x-direction and a y-direction, respectively.

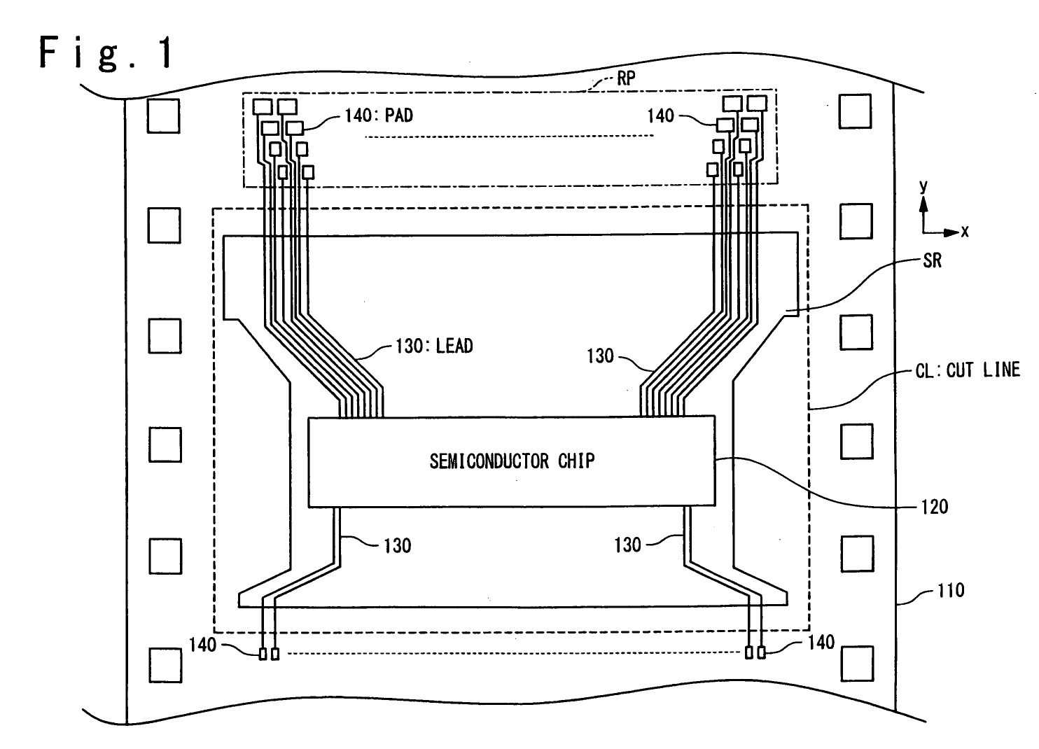

A plurality of semiconductor devices 1 are mounted on the base film 10. More specifically, the base film 10 has a plurality of device regions RD that are placed in series along the y-direction. Each of the device regions RD is a region surrounded by a cut line CL on the base film 10. The plurality of semiconductor devices 1 are placed within the plurality of device regions RD, respectively. That is, the semiconductor device 1 is placed repeatedly along the y-direction on the semiconductor device 1. On separating the semiconductor device one by one, the base film 10 is cut along a cut line CL. It should be noted in the present embodiment that the pad placement region RP as shown in FIG. 1 is not provided on the base film 10. As shown in FIG. 2, only the device region RD appears repeatedly.

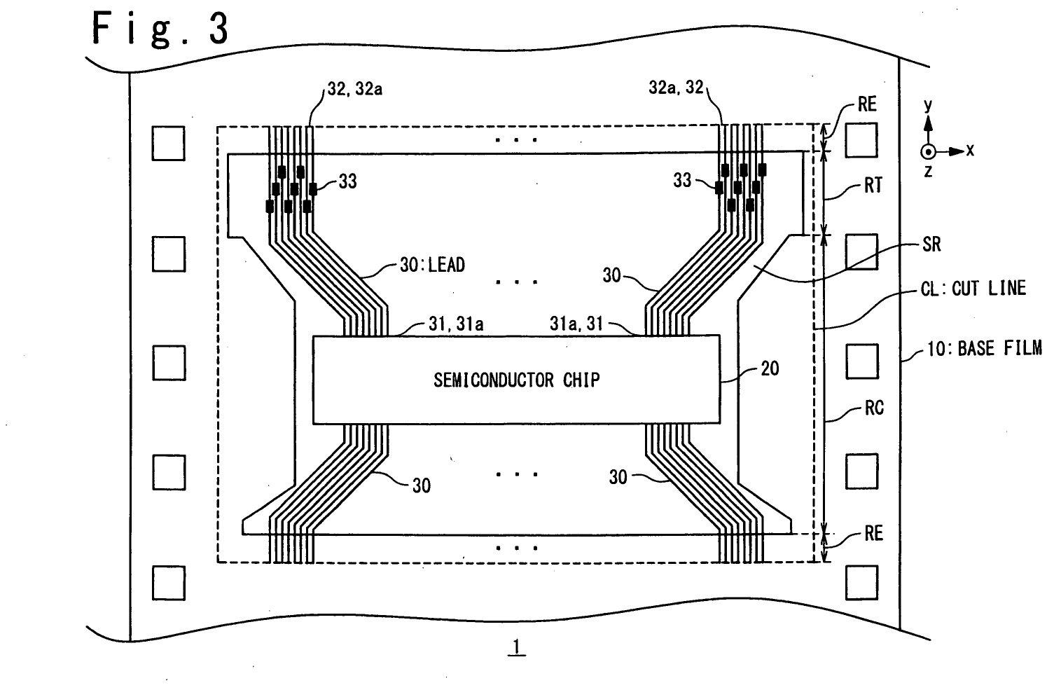

FIG. 3 shows the TCP type semiconductor device as one unit. As shown in FIG. 3, one semiconductor device 1 has a semiconductor chip 20 mounted on the base film 10 and a plurality of leads 30 formed on the base film 10. The plurality of leads 30 are electrically connected to the semiconductor chip 20. More specifically, each of the leads 30 has: a chip connection section 31 including one end (first end section 31a) thereof; and an external terminal section 32 including the other end (second end section 32a) thereof. The chip connection section 31 among them is connected to the semiconductor chip 20. On the other hand, the external terminal section 32 is located on the opposite side of the chip connection section 31.

Moreover, as shown in FIG. 3, solder resist SR is so formed as to partially cover each lead 30. The solder resist SR is resin applied on the lead 30 and plays roles of not only electrically isolating the leads 30 but also relaxing chemical stress such as corrosion and physical stress on the leads 30 due to external force. The lead 30 in a region where the solder resist SR is not formed serves as a terminal that is electrically connectable to the outside, namely the above-mentioned chip connection section 31 and external terminal section 32. The semiconductor chip 20 is mounted on a central region in which the solder resist SR is not formed, and then it is resin-sealed. On the other hand, the external terminal section 32 is exposed and serves as an external connection terminal used for connection with another device. For example, in a case where the semiconductor chip 20 is an IC for driving a liquid crystal display panel, the external terminal sections 32 are connected to electrodes of the liquid crystal display panel. As a result, the liquid crystal display panel and the semiconductor chip 20 for driving it are electrically connected with each other. It should be noted that this connection process is generally called OLB (Outer Lead Bonding).

In the present embodiment, the pad placement region RP as shown in FIG. 1 is not provided on the base film 10. That is, the contact pads 140 dedicated to the test as shown in FIG. 1 are not provided and thus the pad placement region RP is excluded from the base film 10. As shown in FIG. 3, the external terminal section 32 (second end section 32a) of each lead 30 is not connected to a test-dedicated contact pad and serves as termination of the lead 30. All the leads 30 are formed inside of the cut line CL and do not protrude outward from the cut line CL.

According to the present embodiment, at the time of testing the semiconductor chip 20, a special contact pad is not used for contact with a probe card. Instead, a part of the lead 30 within the device region RD is used for contact with the probe card. This section used for the contact with the probe card is hereinafter referred to as a “test pad section 33”. That is, each lead 30 has the test pad section 33 in addition to the chip connection section 31 and the external terminal section 32 described above. More specifically, as shown in FIG. 3, the test pad section 33 of each lead 30 is provided at a position other than the both ends (first end section 31a and second end section 32a) of the lead 30. In other words, the test pad section 33 of each lead 30 is located between the chip connection section 31 and the external terminal section 32 of the lead 30. The test pad section 33 is formed closer to the semiconductor chip 20 than the external terminal section 32 is, and thus obviously located inside of the cut line CL.

As shown in FIG. 3, the device region RD surrounded by the cut line CL on the base film 10 is classified into three regions RE, RT and RC. The first one is an “external terminal region RE” in which the external terminal sections 32 of the leads 30 are formed. The second one is a “test pad region RT” in which the test pad sections 33 of the leads 30 are formed. The third one is a “chip region RC” in which the semiconductor chip 20 is placed. The test pad region RT is sandwiched between the external terminal region RE and the chip region RC. That is, the external terminal region RE is located outermost of the device region RD, the test pad region RT is located on the inner side of the external terminal region RE, and the chip region RC is located on the further inner side.

The external terminal sections 32 need to be exposed, because they are used for connection with another device. Therefore, the entire external terminal region RE is not covered by the solder resist SR. As shown in FIG. 3, among two opposed sides of the external terminal region RE, a side on the side of the semiconductor chip 20 corresponds to one side of a region in which the solder resist SR is formed, and the opposite side corresponds to one side of the cut line CL.

The test pad sections 33 need to be at least exposed, because they are used for contact with the probe card. Therefore, in the test pad region RT, at least a region where the test pad sections 33 are formed is not covered by the solder resist SR. For example, the test pad region RT is basically covered by the solder resist SR and openings of the solder resist SR are respectively formed on the test pad sections 33.

The lead 30 in the chip region RC is basically covered by the solder resist SR and the resin used for sealing the semiconductor chip 20, and thus not exposed.

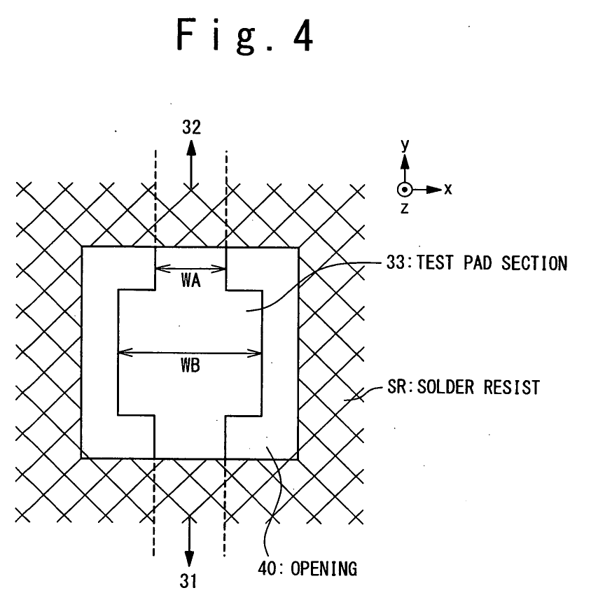

FIG. 4 shows in more detail the test pad section 33 of the lead 30 according to the present embodiment. As described above, the test pad section 33 is located between the chip connection section 31 and the external terminal section 32 of the same lead 30. Moreover, in the test pad region RT, the opening 40 of the solder resist SR is formed over the test pad section 33. As a result, the test pad section 33 is exposed, which enables the contact with a corresponding probe of the probe card. Furthermore, at the time of test, a needlepoint of one probe is prevented from simultaneously coming in contact with two adjacent leads 30. In other words, occurrence of a short failure between the leads 30 is prevented at the time of test.

Here, a width direction of a lead 30 is defined as a direction orthogonal to an extending direction of the lead 30. In FIG. 4 for example, the extending direction of the lead 30 is the y-direction, and the width direction of the lead 30 is the x-direction orthogonal to the extending direction. In this case, the test pad section 33 is so formed as to be wider than the other section, as shown in FIG. 4. In other words, a width WB of the test pad section 33 is greater than a minimum width WA of the other section of the same lead 30. This makes it easier to bring the tip end (needlepoint) of the probe into contact with the test pad section 33 at the time of test.

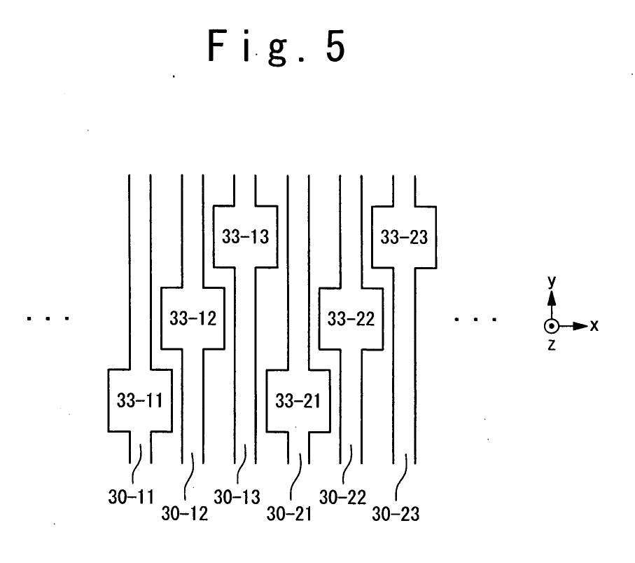

FIG. 5 shows an example of arrangement of the plurality of leads 30 and their test pad sections 33 in the test pad region RT. As an example, leads 30-11 to 30-13 and 30-21 to 30-23 are illustrated. The lead 30-ij (i is any of 1 and 2; j is any of 1 to 3) has a test pad section 33-ij. In the test pad region RT, the plurality of leads 30 are parallel to each other, and the extending direction of each lead 30 is the y-direction. In this case, it is preferable that the position in the y-direction is different between the respective test pad sections 33 of adjacent leads 30, as shown in FIG. 5. For example, the position in the y-direction is different between the respective test pad sections 33-11 and 33-12 of the adjacent leads 30-11 and 30-12. Also for example, the position in the y-direction is different between the respective test pad sections 33-13 and 33-21 of the adjacent leads 30-13 and 30-21.

With the arrangement as shown in FIG. 5, the adjacent leads 30 can be placed more closely to each other without causing short between probes connected to the respective test pad sections 33 of the adjacent leads 30. That is, a pitch between the adjacent leads 30 can be designed smaller. In particular, it is preferable that the respective test pad sections 33 of the adjacent leads 30 are so formed as to partially overlap in the y-direction with each other as shown in FIG. 5. In this case, the test pad sections 33 are arranged in a very efficient manner, the pitch between the adjacent leads 30 can be made smaller, and an area of the base film 10 required for the arrangement of the leads 30 is reduced. This is preferable in terms of miniaturization of the semiconductor device and increase in the number of terminals in recent years.

Furthermore, it is preferable that the respective test pad sections 33 of the plurality of leads 30 are distributed over a plurality of rows in the test pad region RT. For example, as shown in FIG. 5, the test pad sections 33-i1 of the leads 30-i1 are aligned in the x-direction and arranged in a same row. Also, the test pad sections 33-i2 of the leads 30-i2 are aligned in the x-direction and arranged in a same row. Furthermore, the test pad sections 33-i3 of the leads 30-i3 are aligned in the x-direction and arranged in a same row. In other words, the respective test pad sections 33 of the plurality of leads 30 are arranged in a regular manner, and a pattern of the test pad sections 33-i1 to 33-i3 appears repeatedly. This makes it easier to bring the respective probes into one-on-one contact with the corresponding test pad sections 33 at the time of test.

FIG. 6 shows another example of arrangement of the plurality of leads 30 and their test pad sections 33 in the test pad region RT. As shown in FIG. 6, a lead 30 may be so formed as to go around the test pad section 33 of the adjacent lead 30. In this case also, the same effects as in the case of FIG. 5 can be obtained.

According to the present embodiment as described above, at the time of testing the semiconductor chip 20, a special contact pad is not used for contact with the probe card. Instead, the test pad section 33 is formed between the chip connection section 31 and the external terminal section 32 of the lead, and the test pad section 33 is used for the contact with the probe card. Therefore, the contact pads 140 dedicated to test as shown in FIG. 1 are not provided, and the pad placement region RP is excluded from on the base film 10. As a result, a region on the base film 10 required for one semiconductor chip 20 can be greatly reduced as compared with the case of FIG. 1. It is therefore possible to reduce material cost and also to improve efficiency of placing the semiconductor chips 20 on the base film 10. It is thus possible to reduce the costs of manufacturing the semiconductor device 1.

Furthermore, according to the present embodiment, short failure caused by metal burr can be suppressed. As a comparative example, let us consider the case shown in FIG. 1. In the comparative example, the semiconductor chip 120 is connected to the test contact pads 140 through the leads 130. Therefore, on separating the semiconductor chips 120 one by one, it is necessary to cut the leads 130 along the cut line CL. The metal burr generated at this time can cause the short failure later. According to the present embodiment, on the other hand, the test contact pads 140 are not provided. As shown in FIG. 3, the leads 30 are formed only within the device region RD surrounded by the cut line CL. Therefore, on separating the semiconductor chip 20 one by one, cutting of the leads 30 is not performed. As a result, the short failure caused by the metal burr can be suppressed. In addition, a jig used for separating the semiconductor device 1 one by one need not cut the metal lead 30, and thus the jig life is increased.

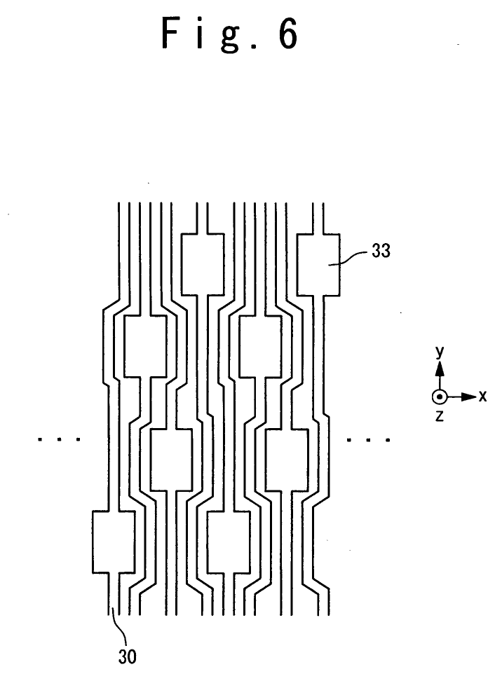

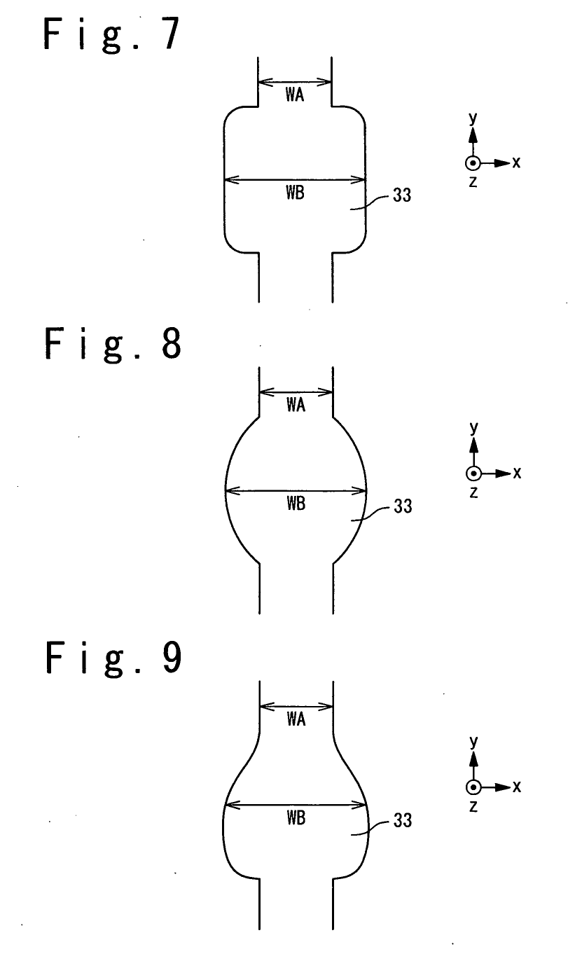

Note that a planar shape of the test pad section 33 is not limited to rectangle as shown in FIG. 4. The test pad section 33 of each lead 30 is just formed wider than the other section of the same lead 30. For example, as shown in FIG. 7, the planar shape of the test pad section 33 may be a rectangle with round corners. As shown in FIG. 8, the planar shape of the test pad section 33 may be oval. As shown in FIG. 9, the planar shape of the test pad section 33 may be a tear-drop shape.

It is apparent that the present invention is not limited to the above embodiments and may be modified and changed without departing from the scope and spirit of the invention.

What is claimed is:

1. A TCP-type semiconductor device comprising:
a base film;
a semiconductor chip mounted on said base film; and
a plurality of leads formed on said base film and electrically connected to said semiconductor chip,
wherein each of said plurality of leads comprises a test pad section at a position other than both ends of said each lead.

2. The TCP-type semiconductor device according to claim 1,
wherein said each lead further comprises:
a chip connection section including one end of said each lead and connected to said semiconductor chip; and
an external terminal section including the other end of said each lead and located on the opposite side of said chip connection section,
wherein said test pad section is located between said chip connection section and said external terminal section, and
wherein said external terminal section and said test pad section are exposed.

3. The TCP-type semiconductor device according to claim 1,
wherein a width of said test pad section of said each lead is greater than a minimum width of the other section of said each lead.

4. The TCP-type semiconductor device according to claim 1,
wherein said test pad section of said each lead is formed in a test pad region on said base film,
an extending direction of said each lead in said test pad region is a first direction,
said plurality of leads include a first lead and a second lead that are adjacent to each other, and
said first lead and said second lead are different in a position of said test pad section in said first direction.

5. The TCP-type semiconductor device according to claim 4,
wherein said test pad section of said first lead and said test pad section of said second lead partially overlap in said first direction with each other.

6. A TCP-type semiconductor device comprising:
a base film having a plurality of device regions each of which is surrounded by a cut line, wherein said base film is cut along said cut line; and
a plurality of semiconductor devices placed within said plurality of device regions, respectively,
wherein each of said plurality of semiconductor devices comprises:
a semiconductor chip mounted on said base film; and
a plurality of leads formed on said base film and electrically connected to said semiconductor chip,
wherein each of said plurality of leads comprises a test pad section at a position other than both ends of said each lead.

7. The TCP-type semiconductor device according to claim 6,
wherein a width of said test pad section of said each lead is greater than a minimum width of the other section of said each lead.

8. The TCP-type semiconductor device according to claim 6,
wherein said plurality of device regions are placed in series along an extending direction of said base film,
wherein in said each semiconductor device, said plurality of leads include a first lead and a second lead that are adjacent to each other, and
said first lead and said second lead are different in a position of said test pad section in said extending direction.
